(19) United States
(12) Patent Application Publication
(10) Pub. No.: US 2001/0002793 A1
(43) Pub. Date: Jun. 7, 2001

(54) Detector device

(76) Inventors: Robert Charles Bryan Woodhead, Auckland (NZ); Nicholas Andrew Fenwick, Auckland (NZ)

Correspondence Address: BLAKELY SOKOLOFF TAYLOR & ZAFMAN, 12400 Wilshire Boulevard, Seventh Floor, Los Angeles, CA, 90025-1026, US

(21) Appl. No.: 09/728,352

(22) Filed: Dec. 1, 2000

(30) Foreign Application Priority Data
Dec. 2, 1999 (NZ) 501475

(51) Int. Cl. G01R 27/28

(52) U.S. Cl. 324/654

(57) ABSTRACT

The detector device includes a sensor 12 that detects an electrical quantity in an electric fence. An audio output 18 is coupled to circuitry which provides a signal to the audio output responsive to an electrical quantity sensed by the sensor 12. The user can, therefore, use aural senses to determine the electrical quantity sensed or differences between electrical quantities sensed at different reading points along a fence line. The detector device can additionally include a digital display 22.

### BACKGROUND OF THE INVENTION

This invention relates to a detector device and more particularly the invention concerns a fault finder device which has particular application with electric fencing.

In the electric fencing industry it is known to provide fault finder apparatus useful for determining faults in the construction or operation of an electric fence. Apparatus of this type measure and indicate the voltage on and current flowing in the fence. The information is displayed in a visual manner by, say, an LCD or LED visual display. The farmer can use this information to trace faults in the electric fence system.

To use apparatus of this type, the farmer will normally walk down the fence line checking the current in the wire periodically or at a junction in the fence system. At a junction point, it is normal to check all of the fence wires coming out of the junction and continue to follow down the track of the wire in which a larger than normal current (which indicates a fault) is flowing. Eventually, the farmer will arrive at the point in the electric fence system which is causing the fault.

Situations are often encountered during such a fault finding exercise where it is not possible to readily view the visual display. For example, at a junction of two or more fence lines the user can inevitably end up physically on the wrong side of the fence or junction. In this situation it can be difficult to reach over the fence closest to the user to engage the instrument with the wire(s) of the other fence line(s) while still being able to view the visual display and (hopefully) not get an electric shock from the near fence. One way of overcoming this problem is to climb over the fence to gain a better advantage point but this obviously is at the risk of receiving an electric shock.

A further problem is the need for good viewing light for the visual display. This leads to a practical problem arising from the habit of many farmers wishing to check fences at dusk so that any small sparks caused by breakdowns can be more easily observed. While a visual display such as a back-lit LCD could be used to overcome this problem there are extra costs involved in producing the instrument and, of course, increased battery consumption.

### SUMMARY OF THE INVENTION

The present invention thus has as its principal object a detector device which can be used for fault finding in an electric fence system which at least goes some way to overcoming the practical problems arising from known detector devices.

Broadly, according to one aspect of the present invention there is provided a detector device including a sensor means for sensing an electrical quantity in an electric fence line, an audio output means and means for providing a signal to the audio output means responsive to an electrical quantity sensed by said sensor means.

### BRIEF DESCRIPTION OF THE DRAWINGS

FIG. 1 is a schematic circuit diagram of a first form of the device, and

FIG. 2 is a similar view of a second form of the invention.

FIG. 3 is a schematic view of a further embodiment of the invention based on the second embodiment of FIG. 2.

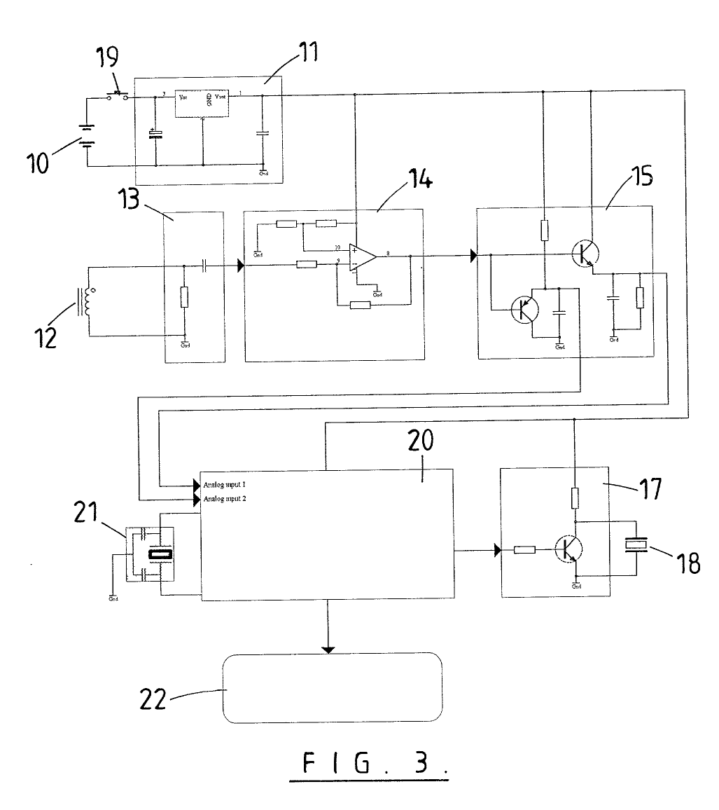

### DETAILED DESCRIPTION OF THE PREFERRED EMBODIMENTS

The detector device according to the present invention is a portable unit which is hand held in its preferred form. The device is therefore powered by a battery 10 with associated power supply control circuitry 11. The arrangement of the circuitry is in accordance with known techniques which will be readily apparent to the skilled person and therefore does not require further description for the purposes the present specification.

The device includes a small pick-up device 12 which in use of the device is positioned adjacent to (generally orthogonal to) a fence line F. According to the simplest form device 12 may be a wire coil or hall effect sensor. For ease of reference device 12 will herein be described simply as a coil. In the drawings the arrows on the fence line F indicate the direction of current flow.

Coil 12 supplies a current signal to the signal conditioner 13 which consists of a resistor to convert the current to a voltage. The signal conditioner may also include filters to decrease unwanted features of the signal. The conditioned signal is then amplifiedby amplifier 14 and applied to a (peak) sample and hold circuit 15 which is connected to a voltage to frequency converter 16.

The output from the converter 16 is via an audio power amplifier 17 used to drive an audio output device 18. In the preferred form of the invention device 18 is a piezo sounder. Consequently, the device operates by representing fence current pulse levels by converting these captured values into audible tones for output on an audio output transducer.

Preferably the device includes a user control switch 19. The switch 19 will permit a user to choose the time period when a new sample signal may be taken. Switch 19 can also be coupled with an on/off control means to minimise power consumption from the battery.

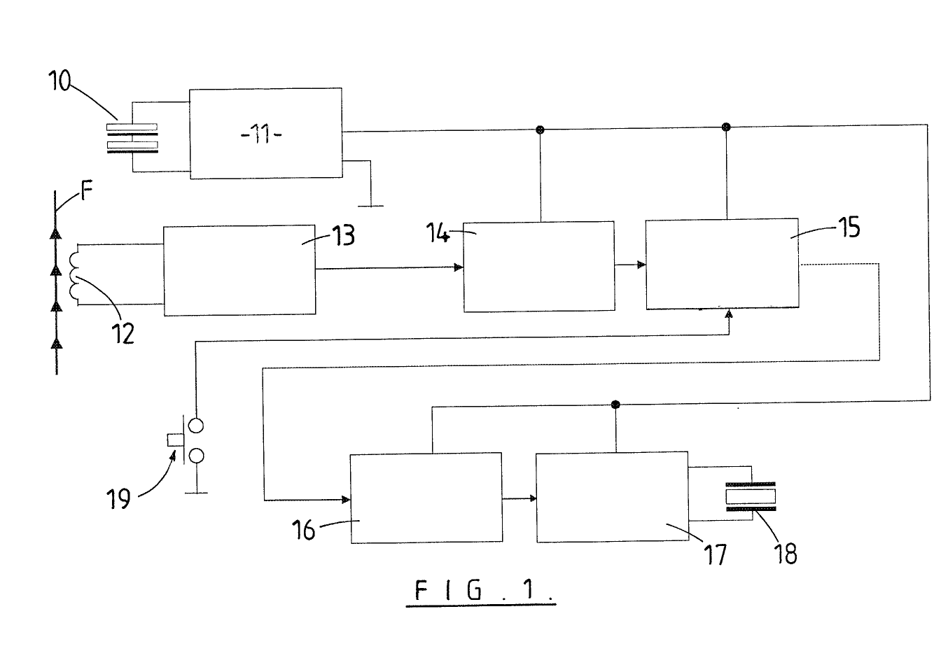

In the example shown in FIG. 1, no visual display is present though in an alternative form such a display would be provided. The (peak) fence currents detected via the coil 12 are, therefore, translated into audible frequencies, eg the higher the (peak) current, the higher the frequency. Consequently, the user of the detector device only needs to listen to different tones produced at each wire or at each reading. The higher frequency tones would indicate where the main current is flowing and thus where the fault is. For example, for very low currents or “no currents” the device could be arranged to produce a very low frequency or no audible output at all.

Advantages of such an arrangement are that the human ear can relay information to the brain quickly thus the user will be able to determine more quickly the current flowing than is the case when using a device having a visual output. In addition, the attention of the user is not visually diverted away from what he or she is doing and an audible warning of the electric fence is given. There is thus less chance of inadvertently touching live parts of the fence wire

Electric fence peak currents can range up to 200 A but typically they are less than 100 A, most being less than 25 A. A standard analogue voltage to frequency converter 16 has no problem operating over the required 200:1 range with repeatable accuracy.

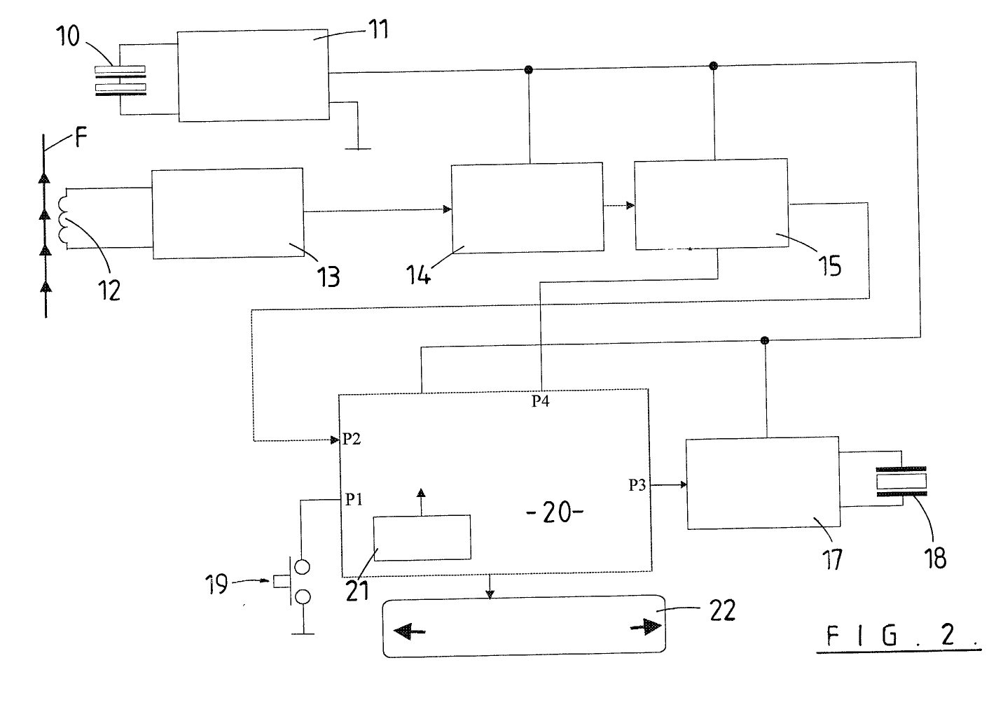

In a more preferred form of the invention as shown in FIG. 2, a digital micro-controller 20 is used to produce the sound tones. In FIG. 2, the circuit components which are the same as those in FIG. 1 carry the same reference numerals.

The micro-controller 20 has programmable features and an internal oscillator 21. A digital current display 22 is, according to this preferred form of the invention, coupled to the micro-controller either directly as shown, or via a separate integrated circuit (or circuits) configured and suitable to drive such a display. The audio output device 18 can be driven by the audio power amplifier 17 or alternatively driven directly by one or more of the micro-controller's output port lines.

The use of a micro-controller enables the device to produce (store) discrete tone readings that are more easily distinguishable than continuous tone variation. For example, a tone “A” could be used to indicate, say, 0.5-0.75 ampere, a tone “B” for 0.75-1 amperes and tone “C” for 1-2 amperes, etc. Therefore, a current reading displayed on the visual display can be associated with distinct tones for within specified ranges of current.

Other advantages of using a micro-controlled device rather than the simple form of the device shown in FIG. 1 include:

Synthesised tones that are pleasing to the ear, eg distinct musical notes over several octaves, for the full range of currents, say, 0 . . 100 amperes. This may be achieved by driving the audio output with a signal created by dividing the microcontroller's clock by a selected amount that is related to a particular range of values within which the detected value lies.

Use of tones (along with the display 22) to warn the user of possible equipment malfunction or dangerous or undesirable fence pulse conditions (eg more than one pulse in every second).

Upon replacing a flat battery the micro-processor could be arranged to play a pleasing tone/tune to indicate that the device is correctly operational.

Use of slight rising or lowering tone shifts to indicate fence current direction, eg low to high current flowing to the left and high to low for current flowing to the right, the “left” and “right” directions being indicated by a “current pointer” associated with the part of the device having the coil 12 so that the pointers have a direction to right or left of the direction of fence line.

For very low currents or “no currents” the device could be arranged to produce a very low frequency (i.e. a distinctly different tone from those of higher currents) or simply a clicking sound to alert the user to the live voltage on the fence.

Tone amplitude modulation, tone length modulation and tone repetition are also further possibilities.

In the second embodiment the micro-controller could provide a direct control of battery energy management in conjunction with the control requirements from the user control switch 19.

The micro-controller can also provide a memory means that would enable the user to review readings taken from previous sections of fence line. For example if the user walked from point A to point B which was some distance from A he may forget what the level of tone was at that point. Also nearly all human users are good at noticing fine changes of pitch but are often not so good with establishing a relationship to absolute pitches.

While the foregoing has referred to the device being used in respect of fence currents, it is not so limited. The device can be arranged to provide fence voltage and/or energy readings. Other modifications within the scope of the present invention will also be apparent to those skilled in the art.

What is claimed is:

1. A detector device including a sensor which in use is locatable adjacent an electric fence line to sense an electrical quantity in the electric fence line, an audio output and signal producing circuitry to provide a signal to the audio output responsive to an electrical quantity sensed by the sensor.

2. A detector device as claimed in claim 1 wherein the sensor is an inductive device responsive to changes in magnetic field about an electric fence wire or tape caused by changes in the current in the wire or tape.

3. A detector device as claimed in claim 1 wherein the sensor is a Hall effect device.

4. A detector device as claimed in claim 1 wherein a signal from the sensor is applied to a signal conditioner and then to an amplifier, the amplifier being coupled to a (peak) sample and hold circuit.

5. A detector device as claimed in claim 4 wherein the output from the (peak) sample and hold circuit is coupled to a voltage to frequency convertor, the output from the voltage to frequency converter being coupled to the audio output via an amplifier.

6. A detector device as claimed in claim 5 wherein the audio output is a piezo sounder.

7. A detector device as claimed in claim 5 further including a visual display device.

8. A detector device as claimed in claim 4 wherein a micro-controller is coupled to the (peak) sample and hold circuit and is also coupled to the audio output either directly or via an amplifier.

9. A detector device as claimed in claim 8 wherein a digital current display is coupled to the micro-controller.

10. A detector device as claimed in claim 8 wherein the micro-controller includes a memory to store readings.

11. A detector device as claimed in claim 10 wherein the memory means stores discrete tone readings or sequences whereby a particular tone or sequence of tones is generated responsive to sensing by the sensor of an electrical quantity within a determined range of quantities.
